(19) United States
(12) Patent Application Publication
(10) Pub. No.: US 2025/0123326 A1
(43) Pub. Date: Apr. 17, 2025

(54) PROBE CARD AND INSPECTION SYSTEM

(71) Applicant: Kabushiki Kaisha Nihon Micronics, Tokyo (JP)

(72) Inventors: Hisao NARITA, Aomori (JP); Hideki HIROTA, Aomori (JP); Shogo SHIMOZAWA, Aomori (JP)

(21) Appl. No.: 18/719,782

(22) PCT Filed: Oct. 25, 2022
(86) PCT No.: PCT/JP2022/039767

§ 371 Date: Dec. 20, 2024

(30) Foreign Application Priority Data
Jan. 12, 2022 (JP) 2022-003026

(51) Int. Cl. G01R 31/28; G01R 1/073

(52) U.S. Cl. CPC G01R 31/2891; G01R 1/07342

(57) ABSTRACT

A probe card includes a probe guide for holding a probe and a probe substrate stacked on the probe guide. The probe substrate has a first surface facing a tester head and a second surface facing the probe guide, and a through hole passing through from the first surface to the second surface is disposed therein. The probe guide abuts the probe substrate due to an inside of the through hole being evacuated while the probe substrate abuts the tester head by means of vacuum adsorption.

### TECHNICAL FIELD

The present invention relates to a probe card and an inspection system used for inspecting an object to be inspected.

### BACKGROUND ART

To inspect electrical characteristics of an object to be inspected such as a semiconductor integrated circuit in a state where the object to be inspected is formed on a wafer, a probe card equipped with a probe for contacting the object to be inspected is used. A tester used for inspecting the object to be inspected includes a measuring device for measuring the electrical characteristics and a tester head connected to the measuring device. In inspecting the object to be inspected, the probe card is connected to the tester head. A method of connecting the probe card to the tester head by means of vacuum adsorption has been investigated (see Patent Literature 1).

For the probe card, a structure is used, which is obtained by stacking a probe substrate on which a wiring pattern connected to the probe is formed, on a probe guide for holding the probe. The probe substrate located on an upper side of the probe card is adsorbed to the tester head by means of vacuum adsorption.

### CITATION LIST

### Patent Literature

Patent Literature 1: JP 2008-288286 A

### SUMMARY OF THE INVENTION

### Problems to be Solved by the Invention

Due to the probe substrate being adsorbed to the tester head, the probe guide located on a lower side of the probe card is warped, and this causes a problem of inhibiting the connection between the probe held on the probe guide and the probe substrate. An object of the present invention is to provide a probe card which is connected to a tester head by means of vacuum adsorption and ensures the connection between a probe and a probe substrate, and an inspection system.

One aspect of the present invention provides a probe card including a probe guide for holding a probe and a probe substrate stacked on the probe guide. The probe substrate has a first surface facing a tester head and a second surface facing the probe guide, and a through hole passing through from the first surface to the second surface is disposed therein. The probe guide abuts the probe substrate due to an inside of the through hole being evacuated while the probe substrate abuts the tester head by means of vacuum adsorption.

### Advantageous Effect of the Invention

According to the present invention, it is possible to provide a probe card which is connected to a tester head by means of vacuum adsorption and ensures the connection between a probe and a probe substrate, and an inspection system.

### BRIEF DESCRIPTION OF THE DRAWINGS

FIG. 1 is a schematic view showing a configuration of an inspection system according to an embodiment.

FIG. 2 is a schematic cross-sectional view in which a region A of FIG. 1 is enlarged.

FIG. 3 is a schematic view showing a state where a probe card according to an embodiment is not vacuum-adsorbed.

FIG. 4 is a schematic view showing a configuration of a probe card of a comparative example.

FIG. 5 is a schematic view showing a configuration of a probe card of another comparative example.

FIG. 6A is a schematic view showing a configuration of a tester.

FIG. 6B is a schematic view showing configurations of measurement parts in a tester.

FIG. 7 is a flowchart for explaining an inspection method performed using a tester having an inspection system according to an embodiment.

FIG. 8 is a schematic plan view showing a configuration of a probe guide of a probe card according to an embodiment.

### MODES FOR CARRYING OUT THE INVENTION

Next, an embodiment of the present invention will be described with reference to the drawings. In the description of the drawings below, the same or similar parts are denoted with the same or similar reference numerals. However, it should be noted that the drawings are schematically shown and ratios of thicknesses of each part and the like are different from those in reality. Further, it is needless to say that the drawings include portions where the relationships and ratios of dimensions are different between drawings. In addition, an embodiment described below exemplifies devices and methods for embodying technical ideas of the invention, and does not specify materials, shapes, structures, arrangements, and the like of components.

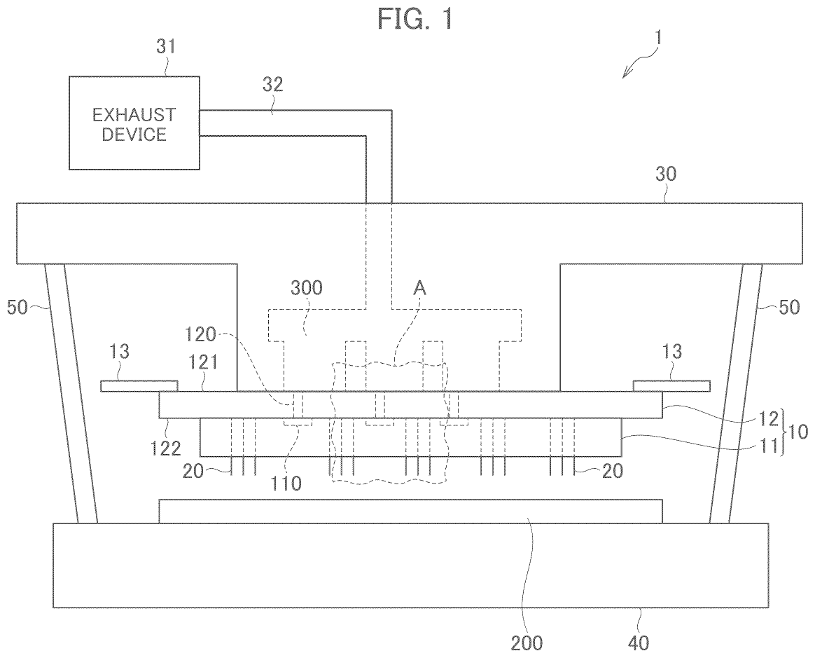

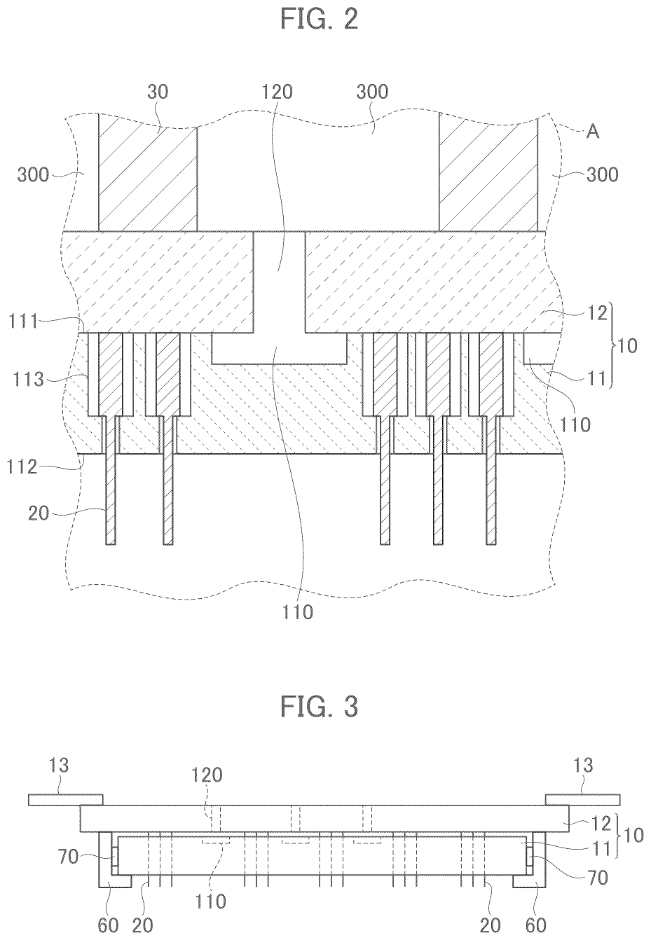

An inspection system 1 according to an embodiment of the present invention shown in FIG. 1 is used for inspecting an object to be inspected formed on a wafer 200 to be inspected. As shown in FIG. 1, the inspection system 1 includes a probe card 10, probes 20, and a tester head 30. FIG. 2 shows an enlarged cross-sectional view of a region A of FIG. 1.

The probe card 10 is equipped with the probes 20 for contacting the object to be inspected. As will be described in detail later, the probe card 10 is connected to the tester head 30 by means of vacuum adsorption. The probe card 10 has a probe guide 11 for holding the probes 20 and a probe substrate 12 stacked on the probe guide 11.

As shown in FIG. 2, the probe guide 11 has guide holes 113 passing through the probe guide 11 from an upper surface 111 to a lower surface 112 of the probe guide 11. The probe guide 11 holds the probes 20 with the probes 20 passing through the inside of the guide holes 113. As shown in FIG. 2, portions of each probe 20 with different outer diameters are connected, and portions of each guide hole 113 with different inner diameters are connected, for example. Each probe 20 is prevented from falling from the probe guide 11 due to an end of a portion of each probe 20 with a large outer diameter abutting on a portion of each guide hole 113 where an inner diameter becomes small. Further, the probes 20 can be arranged at prescribed positions by appropriately setting positions of the guide holes 113.

The wafer 200 faces tips of the probes 20 extending from the lower surface 112 of the probe guide 11. The wafer 200 is mounted on a chuck 40. An adsorption device (not shown) is mounted on the chuck 40, and the wafer 200 is vacuum-adsorbed on the chuck 40.

The inspection system 1 is a vertically operated probe card, and when the object to be inspected is inspected, the tips of the probes 20 contact with the object to be inspected. FIG. 1 shows a state where the probes 20 are not in contact with the object to be inspected. During measurement, the chuck 40 on which the wafer 200 is mounted is raised, and the tips of the probes 20 are in contact with the object to be inspected, for example.

Recesses 110 are formed in the upper surface 111 of the probe guide 11 facing the probe substrate 12. The recesses 110 are formed in a remaining region other than a region where the guide holes 113 are formed. The recesses 110 and the guide holes 113 are not communicated.

The probe substrate 12 has a first surface 121 facing the tester head 30 and a second surface 122 facing the probe guide 11. Through holes 120 passing through from the first surface 121 to the second surface 122 are disposed in the probe substrate 12. In a state where the probe guide 11 and the probe substrate 12 are stacked, each recess 110 is arranged at a position continuous with an opening of each through hole 120 formed in the second surface 122. That is, the through holes 120 formed in the second surface 122 of the probe substrate 12 are continuous with the recesses 110 arranged in the probe guide 11.

The tester head 30 is arranged on the first surface 121 of the probe substrate 12 of the probe card 10. A cavity 300 is formed in the tester head 30. An opening of the cavity 300 is formed in a surface of the tester head 30 facing the first surface 121 of the probe substrate 12. That is, the opening of the cavity 300 faces the first surface 121. The tester head 30 and the probe substrate 12 are arranged such that the cavity 300 in the tester head 30 and the through holes 120 of the probe substrate 12 are continuous. In other words, the through holes 120 are formed at positions where the through holes 120 communicate with the cavity 300 formed in the tester head 30 when the probe substrate 12 abuts the tester head 30.

A proximal end of each probe 20 exposed at the upper surface 111 of the probe guide 11 is connected with a wiring pattern disposed on the second surface 122 of the probe substrate 12. The wiring pattern disposed on the second surface 122 is connected with a wiring pattern disposed on the first surface 121 of the probe substrate 12 via internal wiring disposed inside the probe substrate 12. The wiring pattern disposed on the second surface 122 is connected to an electrode terminal disposed in the tester head 30. The electrode terminal of the tester head 30 is electrically connected to a measuring device (not shown) of a tester.

An exhaust device 31 is mounted on the tester head 30, the exhaust device 31 being connected to the cavity 300 via a duct 32. The exhaust device 31 evacuates an inside of the cavity 300. When the inside of the cavity 300 is evacuated, the inside of the cavity 300 is in a state of lower pressure than the atmosphere. As a result, the probe substrate 12 is vacuum-adsorbed to the tester head 30 while the wiring pattern arranged on the first surface 121 of the probe substrate 12 is in contact with the electrode terminal of the tester head 30.

Further, due to the inside of the cavity 300 being evacuated, an inside of each through hole 120 is evacuated. In accordance with the evacuation of an inside of each through hole 120, an inside of each recess 110 of the probe guide 11 is evacuated. Therefore, an inside of each through hole 120 and an inside of each recess 110 are in a state of lower pressure than the atmosphere. As a result, the probe guide 11 abuts the probe substrate 12 by means of vacuum adsorption while the proximal ends of the probes 20 are connected to the wiring pattern disposed on the second surface 122 of the probe substrate 12. In other words, according to the inspection system 1, the probe guide 11 and the probe substrate 12 can be integrally connected to the tester head 30 by means of vacuum adsorption. Hereinafter, an operation of integrally connecting the probe guide 11 and the probe substrate 12 to the tester head 30 by means of vacuum adsorption will also be referred to as “adsorption contact”.

As described above, in the inspection system 1, the probe guide 11 abuts the probe substrate 12 at approximately the same time when the probe substrate 12 abuts the tester head 30 by means of vacuum adsorption. That is, the probe guide 11 abuts the probe substrate 12 due to an inside of each through hole 120 being evacuated while the probe substrate 12 abuts the tester head 30. At this time, the object to be inspected formed on the wafer 200 and the measuring device of the tester are electrically connected via the probes 20, the probe card 10, and the tester head 30. That is, in the inspection system 1, a signal is transmitted and received between the object to be inspected and the measuring device of the tester.

Levers 13 for conveying connected to the probe card 10 shown in FIG. 1 are handles for holding the probe card 10 when the probe card 10 is conveyed. A region where the probe card 10 and the tester head 30 are connected is shielded from an outside by vacuum sheets 50. The interior of each vacuum sheet 50 can be maintained at lower pressure than atmospheric pressure.

By arranging the recesses 110 in the upper surface 111 of the probe guide 11, the vacuum-adsorption area is increased. Therefore, adsorption force for adsorbing the probe guide 11 to the probe substrate 12 increases. It is preferable to arrange the recesses 110 over the entire area of the upper surface 111 of the probe guide 11 to prevent the probe guide 11 from warping. Further, a plurality of recesses 110 may be formed in the upper surface 111 of the probe guide 11. The plurality of recesses 110 may be communicated. By communicating the recesses 110 with each other, at least one portion of the recesses 110 is continuous with the through holes 120 in the probe substrate 12, and therefore the inside of all the recesses 110 can be evacuated. When all the recesses 110 are communicated, the number of through holes 120 in the probe substrate 12 may be one.

If the probe card 10 is not connected to the tester head 30 by means of vacuum adsorption, the probe guide 11 and the probe substrate 12 are separated as shown in FIG. 3. As shown in FIG. 3, outer edges of the probe guide 11 may be supported by fixing rings 60 disposed at outer edges of the probe substrate 12 to prevent the probe guide 11 from falling when the probe card 10 is conveyed using the levers 13 for conveying as handles. It is necessary that lower ends of the fixing rings 60 do not come into contact with the wafer 200 in a state where the probes 20 shrink the most during the inspection of the object to be inspected. By arranging the fixing rings 60 in recesses formed at the outer edges of the probe substrate 12, portions of the lower ends of the fixing rings 60 extending from a lower surface of the probe card 10 is reduced, for example.

The proximal ends of the probes 20 are pressed against the probe substrate 12 by means of the adsorption contact. Pressing force applied to the probe substrate 12 from the probes 20 during a non-inspection period is also referred to as “preload force”. In the inspection system 1, the preload force is applied to the probe substrate 12 by means of the adsorption contact. By means of the preload force, the proximal ends of the probes 20 can be in contact with the probe substrate 12 at all times. The preload force is set such that the probe guide 11 is not warped in accordance with the number of probes 20 and the rigidity of the probe guide 11.

If a state where the probe substrate 12 and the probes 20 are not contacted continues, the proximal ends of the probes 20 and a surface of the wiring pattern of the probe substrate 12 are oxidized or dirt is adhered thereto. Further, if the probe substrate 12 and the probes 20 are contacted and not contacted repeatedly, breakages may occur to the probe substrate 12 and the probes 20. As a result, poor contact between the probe substrate 12 and the probes 20 occurs. The occurrence of poor contact between the probe substrate 12 and the probes 20 can be suppressed by contacting the probe substrate 12 and the probes 20 all the time.

As shown in FIG. 3, vacuum sealing mechanisms 70 may be arranged between the fixing rings 60 and the probe guide 11. The vacuum sealing mechanisms 70 block a boundary between the probe guide 11 and the probe substrate 12 from an outside. The vacuum sealing mechanisms 70 can suppress vacuum leakage from the boundary between the probe guide 11 and the probe substrate 12 at the start of vacuum adsorption. O-rings are used for the vacuum sealing mechanisms 70, for example.

A highly rigid material is used for the probe guide 11 to suppress warp. Further, for the probe guide 11, a material is used which responds to the change in positions of the tips of the probes 20 due to a thermal expansion coefficient of the wafer 200 and a reaching temperature of the probe guide 11 during inspection. That is, for the probe guide 11, a material is used which has a thermal expansion rate capable of ensuring a margin (pad edge margin) in which the positions of the tips of the probes 20 do not extend from an electrode pad of the object to be inspected.

Incidentally, for the probes 20, probes that can be freely extended and contracted in an axially direction such as pogo pins are used, for example. The contact can be reliably performed by using the probes 20 that can be freely extended and contracted. Meanwhile, by using the probes 20 that can be freely extended and contracted, pressing force (hereinafter also referred to as “load”) is applied to the probe substrate 12 from the probes 20. In addition, the load applied to the probe substrate 12 at the time of inspection increases due to the overdrive of pressing the probes 20 against the object to be inspected. In particular, in a case of a collective test in which a large number of objects to be inspected are simultaneously inspected on the wafer 200 having a large area, the load of the probe substrate 12 is large because the number of probes 20 is large.

In a case of a collective test using a wafer 200 having a diameter of 300 nm, the number of probes 20 to be mounted on the probe card 10 is tens of thousands or more due to reduction in size of chips as the objects to be inspected, for example. In this case, the load of the probe substrate 12 is 100 kgf or more. Therefore, in order to withstand the load of the probe substrate 12, a casing of the inspection system has a problem of being heavy. If the casing is heavy, a ground contact area (footprint) of the inspection system increases, and the inspection cost increases.

By adsorbing the probe card to the tester head by means of vacuum adsorption, the casing of the inspection system can be reduced in size. However, in order to reduce a space for implementing the inspection system, it is necessary to reduce a length of each probe and reduce a thickness of the probe guide. Therefore, the following problems arise in the inspection system employing the method of adsorbing the probe substrate to the tester head.

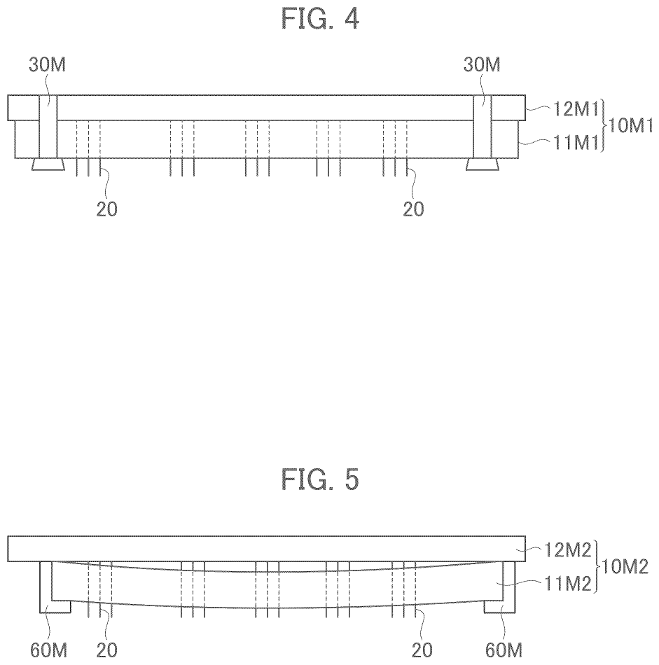

FIG. 4 shows a first comparison probe card 10M1 as a comparative example of the inspection system 1. The first comparison probe card 10M1 is obtained by connecting a probe guide 11M1 and a probe substrate 12M1 using fixing screws 30M. Therefore, the probe card is required to have a space for arranging the fixing screws 30M, and reduction in size of the probe card is inhibited. An assembly process of the probe card is complicated. Further, there is a risk of the occurrence of vacuum leakage from screw holes through which the fixing screws 30M are passed. In addition, there is a risk that the probe guide 11M1 may be warped due to a weight thereof between the fixing screws 30M. Due to the probe guide 11M1 being warped, proximal ends of probes 20 disposed on the probe guide 11M1 may not be in contact with the probe substrate 12M1 all the time.

FIG. 5 shows a second comparison probe card 10M2 as another comparative example of the inspection system 1. In the second comparison probe card 10M2, outer edges of a probe guide 11M2 and outer edges of a probe substrate 12M2 are connected using fixtures 60M. In the second comparison probe card 10M2, only the outer edges of the probe guide 11M2 are connected to the probe substrate 12M2. Therefore, a central part of the probe guide 11M2 may be warped due to preload force as shown in FIG. 5. Due to the central part of the probe guide 11M2 being warped, proximal ends of probes 20 disposed on the probe guide 11M2 may not be in contact with the probe substrate 12M2 all the time.

In contrast to the above comparative examples, in the inspection system 1, the probe guide 11 and the probe substrate 12 are integrally connected to the tester head 30 by means of vacuum adsorption. This eliminates the necessity of a fixing pin or fixture for connecting the probe guide 11 and the probe substrate 12. Therefore, according to the inspection system 1, the size of the probe card can be reduced, and the probes 20 and the probe substrate 12 can be contacted all the time.

As described above, according to the inspection system 1, the probe card 10 is connected to the tester head 30 by means of vacuum adsorption, and connection between the probes 20 and the probe substrate 12 can be ensured.

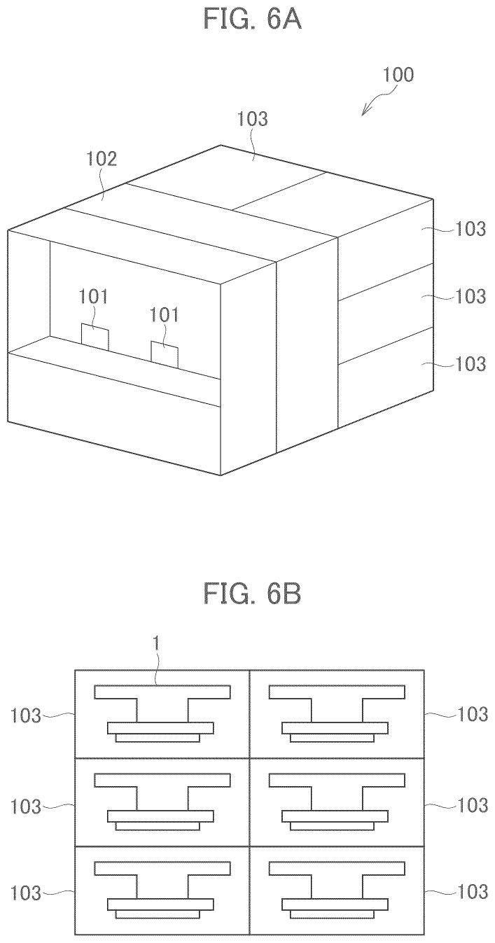

The inspection system 1 shown in FIG. 1 is suitably used for a tester 100 shown in FIGS. 6A and 6B, for example. As shown in FIG. 6A, the tester 100 includes a conveying part 102 for conveying the wafer 200 and a plurality of measurement parts 103 disposed adjacent the conveying part 102. As shown in FIG. 6B, the tester 100 has six measurement parts 103.

The wafer 200 conveyed to the conveying part 102 from conveying ports 101 is conveyed to the measurement parts 103 by the conveying part 102. Then, characteristics of the object to be inspected formed on the wafer 200 are inspected in each measurement part 103. The wafer 200 which has been inspected in the measurement parts 103 is conveyed from the measurement parts 103 to the conveying ports 101 by the conveying part 102.

Hereinafter, a tester having a plurality of measurement parts 103, such as the tester 100, will also be referred to as a “multi-stage tester”. Although an example has been described in which the tester 100 has the six measurement parts 103, the number of measurement parts 103 in the multi-stage tester is not limited to six. The adsorption contact by means of a vacuum adsorption system described above is performed in each measurement part 103 of the multi-stage tester.

In a manufacturing process of a semiconductor device such as a memory device, an increase in size of a wafer and reduction in size of a chip are promoted in order to reduce the manufacturing cost. As a result, the number of chips formed on a single wafer becomes very large. Therefore, enhancement in throughput by reducing the time required for inspection of a single wafer is required.

A measure to increase the number of probers is considered for enhancement of a throughput. However, if the number of probers is increased, a problem occurs in which an installation area of the probers in a manufacturing line increases. Further, if the number of probers is increased, the device cost also increases. Meanwhile, according to an inspection using the multi-stage tester, a throughput is enhanced because a plurality of chips on a wafer can be inspected simultaneously. Further, according to the multi-stage tester, an increase in an installation area of a tester and an increase in the device cost can be suppressed.

Especially, in the multi-stage tester, the probe card is arranged in a very limited and narrow space. As shown in FIG. 6B, each probe card is arranged inside each measurement part 103, for example. Therefore, for the multi-stage tester, the inspection system 1 is suitable used, which is reduced in size by integrally connecting the probe guide 11 and the probe substrate 12 to the tester head 30 by means of vacuum adsorption.

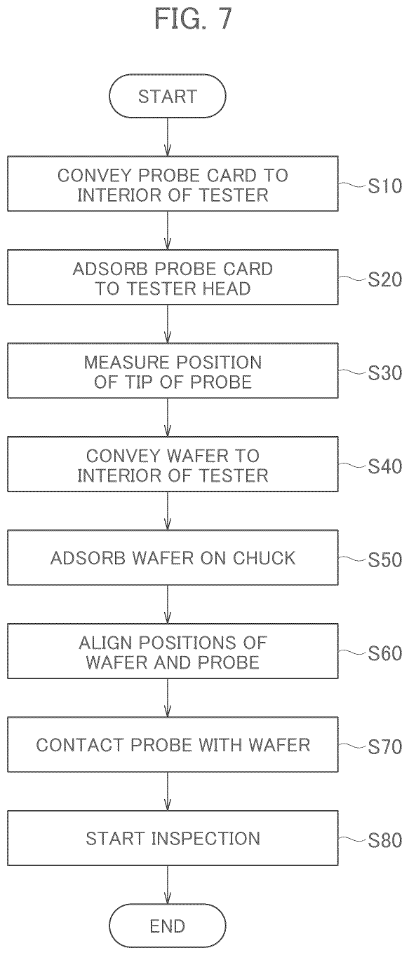

An example of an inspection method performed by the tester 100 using the probe card 10 will be described below with reference to FIG. 7.

First, in step S10, the probe card 10 is conveyed to the interior of the tester 100. The probe card 10 is conveyed to each measurement part 103 in which the tester head 30 and the chuck 40 are arranged, for example.

In step S20, the adsorption contact of adsorbing the probe card 10 to the tester head 30 by means of vacuum adsorption as described above is performed. By means of the adsorption contact, preload force is applied to the probe substrate 12.

In step S30, positions of the tips of the probes 20 are measured. Information on the positions of the tips of the probes 20 is used for the alignment of a position of the wafer 200 and the positions of the probes 20 in step S60, which will be described later.

In step S40, the wafer 200 is conveyed to each measurement part 103 of the tester 100. The wafer 200 conveyed to each measurement part 103 is mounted on the chuck 40. In step S50, the wafer 200 is vacuum-adsorbed on the chuck 40.

In step S60, the position of the wafer 200 mounted on the chuck 40 and the positions of the probes 20 are aligned. Specifically, a position of an electrode pad of an object to be inspected formed on the wafer 200 and the positions of the tips of the probes 20 are aligned using the information on the positions of the tips of the probes 20 measured in step S30.

In step S70, the tips of the probes 20 are brought into contact with the wafer 200. At this time, the tips of the probes 20 are brought into contact with the wafer 200 by changing a position of the chuck 40 relative to the probe card 10. Further, in order to perform overdrive, an operation (hereinafter also referred to as “vacuum contact”) of pressing the tips of the probes 20 against the wafer 200 by means of vacuum adsorption is performed. Then, in step S80, inspection of the object to be inspected formed on the wafer 200 starts.

In the above-described adsorption contact in step S20 and vacuum adsorption in step S50, there is not much need to consider the pressure caused by adsorption. Therefore, adsorption at any high vacuum may be performed. Meanwhile, in the vacuum contact in step S70, the probes 20 and the wafer 200 may be broken due to strong adsorption at a high vacuum. In the vacuum contact, it is necessary to adjust the vacuum to prevent the probes 20 and the wafer 200 from being broken.

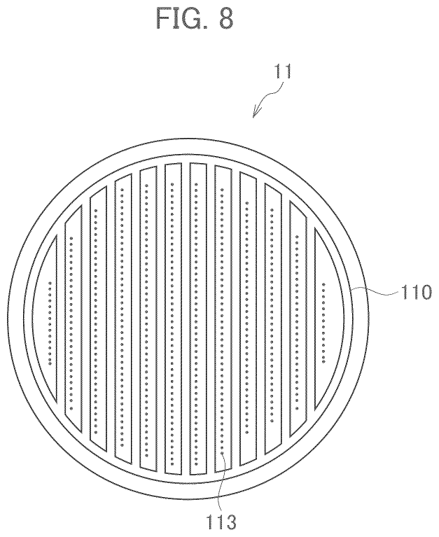

As described above, if all the recesses 110 arranged in the probe guide 11 are communicated with each other, it is sufficient if one portion of the recesses 110 is continuous with the through holes 120 in the probe substrate 12. FIG. 8 shows an example of arrangement of the recesses 110 in the probe guide 11. As shown in FIG. 8, the recesses 110 are arranged in a region where the plurality of guide holes 113 through which the probes 20 are passed through are not arranged.

In the probe guide 11 shown in FIG. 8, the plurality of guide holes 113 are arranged in an arrayed manner. The recesses 110 have an outer edge portion continuously formed along the outer edge of the probe guide 11 and inner portions communicating with the outer edge portion. The inner portions are arranged continuously in regions between the plurality of guide holes 113 in a stripe shape.

The guide holes 113 are arranged in correspondence with positions of electrode pads of objects to be inspected formed on the wafer 200. Therefore, each recess 110 may be arranged at a position of the probe guide 11 in corresponded with a scribe line of the wafer 200 between an object to be inspected and an object to be inspected.

An example of the size of each recess 110 in the probe guides 11 shown in FIG. 8 will be investigated below. If the preload force is 50 kgf or more, it is assumed that 1 atm is approximately 1 kgf/cm², and the size of each recess 110 is 50 cm² or more. In this case, each recess 110 having a width of 3 mm and a length of 1650 mm is formed in the probe guide 11, for example. The depth of each recess 110 is optional, but the depth of each recess 110 is set to be 0.5 mm or more, for example.

If the recesses 110 and the guide holes 113 communicate with each other due to the breakage of the probe guide 11 or the like, there is a risk of the occurrence of vacuum break. For this reason, it is preferable that an interval between each recess 110 and each guide hole 113 is about the depth of each recess 110 or more.

### Other Embodiments

Although an embodiment of the present invention has been described above, the discussion and drawings forming part of this disclosure should not be construed as limiting the present invention. Various alternative embodiments, examples, and operational techniques will be apparent to those skilled in the art from this disclosure.

In the above, the probe guide 11 has been described which has the recesses 110 formed in the upper surface 111 thereof, for example. However, if the probe guide 11 can be adsorbed to the probe substrate 12 by evacuating the inside of the through holes 120 in the probe substrate 12, the recesses 110 may not be disposed in the probe guide 11. In this case, openings of the plurality of through holes 120 are disposed over the entire area of the second surface 122 of the probe substrate 12 so as not to cause warp of the probe guide 11. At this time, the total area of each opening of each through hole 120 is set in accordance with the magnitude of required preload force. If preload force is set to 50 kgf or more, the total area of each opening of each through hole 120 in the second surface 122 is set to 50 cm² or more in the same manner as the size of each recess 110 described above.

In this way, it is needless to say that the present invention includes various embodiments and the like not described herein. Accordingly, the technical scope of the present invention is defined only by the matters used to specify the invention recited in claims that are appropriate from the above description.

### REFERENCE SIGNS LIST

1 Inspection system
10 Probe card
11 Probe guide
12 Probe substrate

### 20 Probe

30 Tester head

### 40 Chuck

### 110 Recess

120 Through hole
121 First surface
122 Second surface

### 200 Wafer

### 300 Cavity

What is claimed is:

1. A probe card to which a probe for contacting an object to be inspected is attached and which is connected to a tester head by means of vacuum adsorption, the probe card comprising:
a probe guide for holding the probe; and
a probe substrate which is stacked on the probe guide and has a first surface facing the tester head and a second surface facing the probe guide, and in which a through hole passing through from the first surface to the second surface is disposed, wherein
the probe guide abuts the probe substrate due to an inside of the through hole being evacuated while the probe substrate abuts the tester head by means of the vacuum adsorption.

2. The probe card according to claim 1, wherein
the probe guide has a recess disposed in an upper surface of the probe guide facing the probe substrate, and
the recess is disposed at a position continuous with an opening of the through hole formed in the second surface in a state where the probe guide and the probe substrate are stacked.

3. The probe card according to claim 2, wherein
the recess is provided in plurality, and the plurality of recesses are formed in a remaining region other than a region where a guide hole which is formed in the probe guide and through which the probe is passed through is formed,
the plurality of the recesses communicate with each other, and
the recesses do not communicate with the guide hole.

4. The probe card according to claim 3, wherein
the guide hole is provided in plurality, and the plurality of guide holes are arranged in the probe guide in an arrayed manner, and
each of the recesses has an outer edge portion formed continuously along an outer edge of the probe guide and an inner portion that communicates with the outer edge portion and is arranged continuously in a region between the plurality of guide holes.

5. The probe card according to claim 1, further comprising:
a vacuum sealing mechanism for blocking a boundary between the probe guide and the probe substrate from an outside.

6. The probe card according to claim 1, wherein
the through hole is formed at a position where the through hole communicates with a cavity formed in the tester head when the probe substrate abuts the tester head.

7. An inspection system comprising:
the probe card according to any one of claims 1 to 6; and
the tester head including an exhaust device, wherein
the exhaust device evacuates an inside of the through hole, and the probe guide and the probe substrate are integrally connected to the tester head by means of the vacuum adsorption.
